(19) United States
(12) Patent Application Publication
(10) Pub. No.: US 2026/0358439 A1
(43) Pub. Date: Nov. 12, 2026

(54) LOW VOLTAGE DISCONNECT DETECTION CIRCUIT

(71) Applicant: GHSP, INC., Holland, MI (US)

(72) Inventors: Kirk Ypma, Rockford, MI (US); John Pacelli, Allegan, MI (US)

(73) Assignee: GHSP, INC., Holland, MI (US)

(21) Appl. No.: 19/673,234

(22) Filed: May 11, 2026

Related U.S. Application Data
(60) Provisional application No. 63/802,950, filed on May 9, 2025.

(51) Int. Cl. G01R 31/69; B60Q 11/00; B60R 25/10; G01R 19/15; G01R 19/155; G01R 31/00

(52) U.S. Cl. CPC G01R 31/69; B60Q 11/007; B60R 25/1001; B60R 25/1004; B60R 25/1018; G01R 19/15; G01R 19/155; G01R 31/006

(57) ABSTRACT

A disconnect detection device includes an operating circuit and a detection circuit that define signal communication between a mechanism and a power source. A switch diverts an electrical signal between the operating and detection circuits. A current/voltage monitor detects the voltage and current components of the electrical signal within the detection circuit. The switch and the current/voltage monitor are coupled with a controller. The mechanism is adapted to activate in the presence of a threshold level of the current and voltage components from the operating circuit. When the switch connects the detection circuit with the power source and the mechanism, an impedance path of the detection circuit delivers a low-level electrical signal of the current component that is below the threshold level such that the mechanism remains deactivated. When the current/voltage monitor fails to detect the current component, the current/voltage monitor delivers a check signal to the controller.

### CROSS-REFERENCE TO RELATED APPLICATION

This application claims priority to and the benefit under 35 U.S.C. § 119(e) of U.S. Provisional Patent Application No. 63/802,950, filed on May 9, 2025, entitled LOW VOLTAGE DISCONNECT DETECTION CIRCUIT, the entire disclosure of which is hereby incorporated herein by reference.

### FIELD OF THE DISCLOSURE

The present disclosure generally relates to detection circuits, and more specifically to a detection circuit that can be used for a vehicle and trailer interface that detects the presence of a voltage and a current while maintaining a low power mode of the device to ensure that the vehicle and trailer interface is connected.

### BACKGROUND OF THE DISCLOSURE

Various circuits are utilized for detecting the presence of a connection between various mechanisms or assemblies. These circuits can be utilized for alerting one to an intentional or inadvertent disconnection of these connections, such as to prevent theft of a portion of the mechanism.

### SUMMARY OF THE DISCLOSURE

According to one aspect of the present disclosure, a disconnect detection device includes an operating circuit, a detection circuit, a switch, and a current/voltage monitor. The operating circuit places a mechanism in signal communication with a power source. The detection circuit is positioned in parallel with the operating circuit and extending between the mechanism and the power source. The detection circuit further defines an impedance path. The switch selectively diverts an electrical signal between the operating circuit and the detection circuit. The current/voltage monitor is coupled with the detection circuit to detect the presence of a voltage component of the electrical signal and the presence of a current component of the electrical signal within the detection circuit. The switch and the current/voltage monitor are coupled with a controller. The mechanism is adapted to activate in the presence of a threshold level of the current component and the voltage component that are delivered by the operating circuit. In the event that the switch connects the detection circuit with the power source and the mechanism, the impedance path directs at least the current component through the mechanism and through the current/voltage monitor as a low-level electrical signal of the current component that is below the threshold level such that the mechanism remains deactivated. In the event that the current/voltage monitor fails to detect the current component, the current/voltage monitor delivers a check signal to the controller.

According to another aspect of the present disclosure, a disconnect detection device includes an operating circuit, a detection circuit, a switch, and a current/voltage monitor. The operating circuit places a trailer in signal communication with a power source of a vehicle. The detection circuit is positioned in parallel with the operating circuit and extending between the trailer and the power source. The detection circuit further defines an impedance path. A switch selectively diverts an electrical signal between the operating circuit and the detection circuit. The electrical signal has a voltage component and a current component. A current/voltage monitor is coupled with the detection circuit to detect the presence of at least the current component within the detection circuit. The switch and the current/voltage monitor are coupled with a controller. The trailer includes electrical components that define an operating state in the presence of the voltage component and the current component that are delivered by the operating circuit and define a threshold level of the voltage component and the current component. In the event that the switch connects the detection circuit with the power source and the trailer, the impedance path defines at least the current component as being at a low-power state where the voltage component and the current component are below the threshold level such that the electrical components of the trailer remain deactivated. In the event that the current/voltage monitor fails to detect the current component, the current/voltage monitor delivers a check signal to the controller.

According to yet another aspect of the present disclosure, a method for detecting the presence of a trailer attached to a vehicle includes the steps of activating a standby mode of the vehicle where power is being transferred from the vehicle to the trailer, deactivating an operating circuit to prevent current from flowing to an aspect of the trailer, activating a detection circuit for delivering a low-level electrical signal to the aspect of the trailer, where the low-level electrical signal includes a voltage component and a current component that are below a threshold level and the low-level electrical signal is a minimum electrical signal that is capable of being detected and incapable of activating the aspect of the trailer, detecting the presence of both the voltage component and the current component of the low-level electrical signal within the detection circuit, and activating a decoupling signal when at least the current component is not detected.

These and other features, advantages, and objects of the present disclosure will be further understood and appreciated by those skilled in the art by reference to the following specification, claims, and appended drawings.

### BRIEF DESCRIPTION OF THE DRAWINGS

In the drawings:

FIG. 1 is a perspective view of a vehicle and trailer that are attached to one another;

FIG. 2 is an enlarged perspective view of the attachment between the trailer and the vehicle showing the connection between the electrical system of the vehicle and the electrical system of the trailer;

FIG. 3 is a schematic diagram illustrating an aspect of the detection circuit;

FIG. 4 is a circuit diagram illustrating an aspect of the detection circuit;

FIG. 5 is a circuit diagram illustrating an aspect of the detection circuit;

FIG. 6 is a schematic diagram illustrating the harness connection between a vehicle and a trailer and showing an aspect of the detection circuit;

FIG. 7 is a schematic diagram illustrating the harness connection between a vehicle and a trailer and showing an aspect of the detection circuit; and

FIG. 8 is a linear flow diagram illustrating a method for operating a detection circuit.

The components in the figures are not necessarily to scale, emphasis instead being placed upon illustrating the principles described herein.

### DETAILED DESCRIPTION

As required, detailed embodiments of the present disclosure are disclosed herein; however, it is to be understood that the disclosed embodiments are merely exemplary of the invention that may be embodied in various and alternative forms. The figures are not necessarily to a detailed design; some schematics may be exaggerated or minimized to show function overview. Therefore, specific structural and functional details disclosed herein are not to be interpreted as limiting, but merely as a representative basis for teaching one skilled in the art to variously employ the present invention.

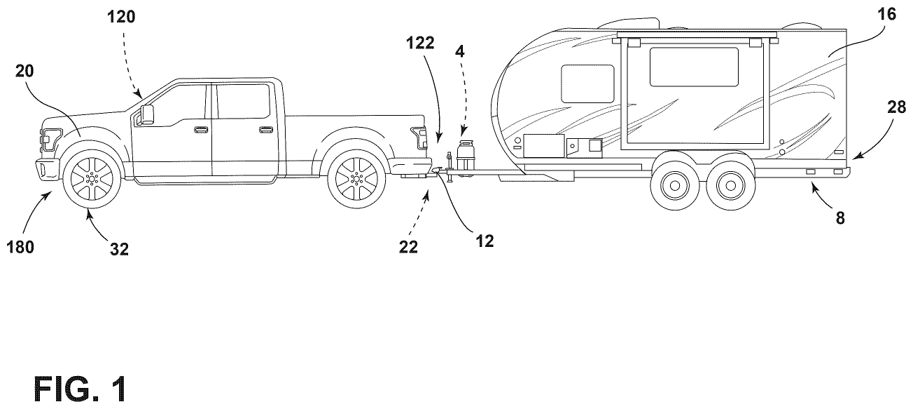

For purposes of description herein, the terms “upper,” “lower,” “right,” “left,” “rear,” “front,” “vertical,” “horizontal,” and derivatives thereof shall relate to the concepts as oriented in FIG. 1. However, it is to be understood that the concepts may assume various alternative orientations, except where expressly specified to the contrary. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

The present illustrated embodiments reside primarily in combinations of method steps and apparatus components related to a detection circuit that can be used for a vehicle and trailer interface that detects the presence of a voltage and a current while maintaining a low power mode of the device. Accordingly, the apparatus components and method steps have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein. Further, like numerals in the description and drawings represent like elements.

As used herein, the term “and/or,” when used in a list of two or more items, means that any one of the listed items can be employed by itself, or any combination of two or more of the listed items, can be employed. For example, if a composition is described as containing components A, B, and/or C, the composition can contain A alone; B alone; C alone; A and B in combination; A and C in combination; B and C in combination; or A, B, and C in combination.

In this document, relational terms, such as “first” and “second,” “top” and “bottom,” and the like, are used solely to distinguish one entity or action from another entity or action, without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

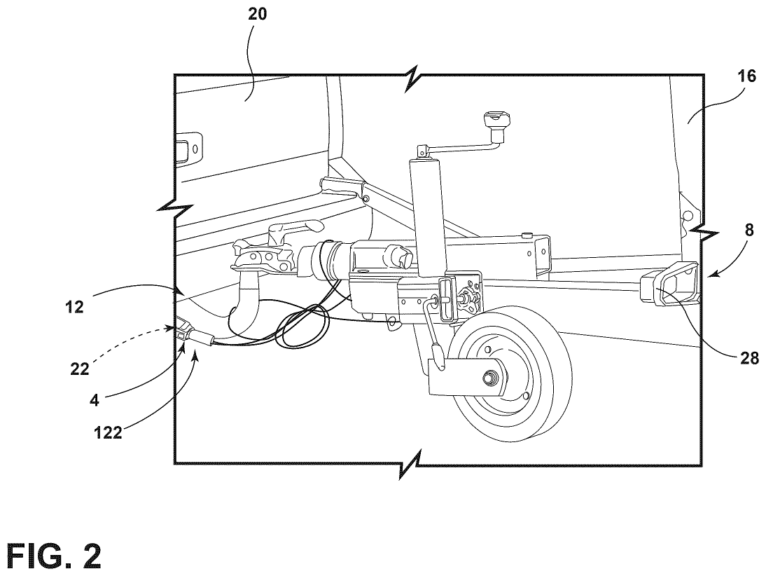

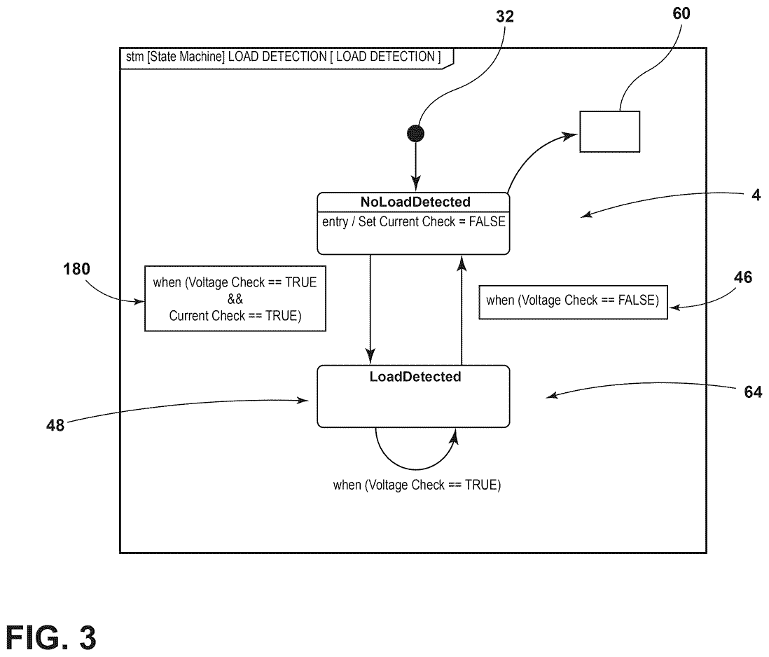

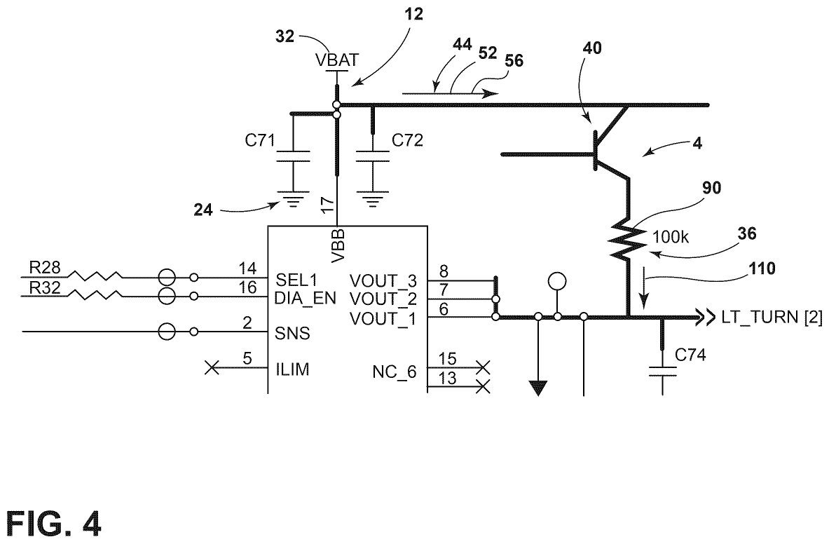

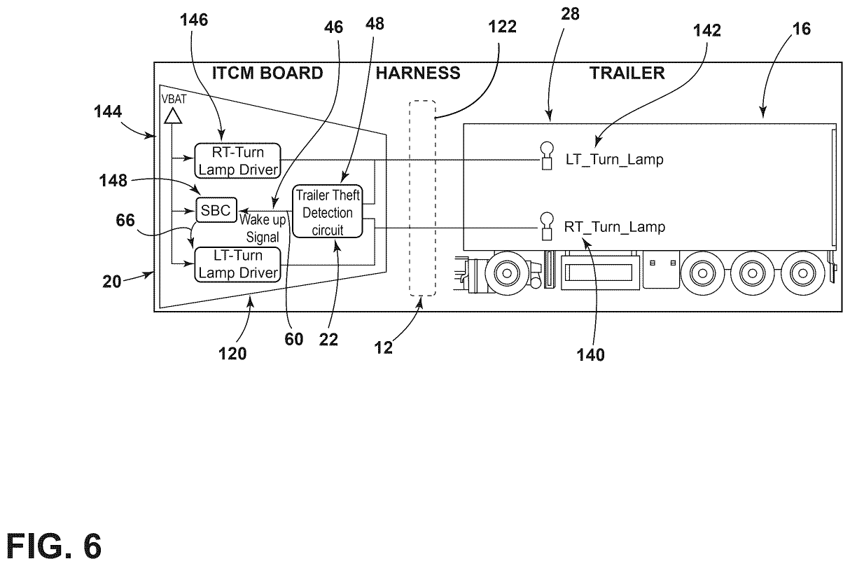

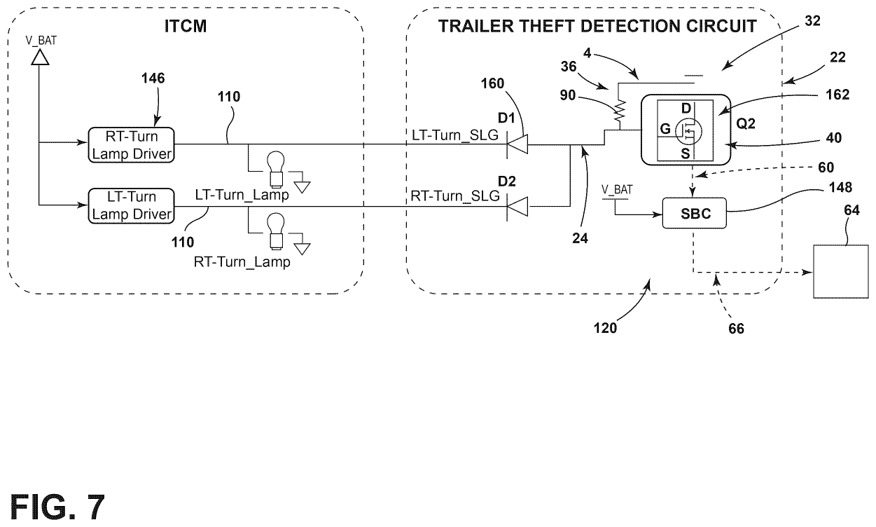

Referring now to FIGS. 1-7, reference numeral 4 generally refers to a detection circuit that can be incorporated within a device 8, such as a vehicle 20 or trailer 16, where the detection circuit 4 detects the presence of a connection 12 between two devices 8. The detection circuit 4 can be utilized, by way of example, and not limitation, for detecting the presence of a trailer 16 attached to a vehicle 20. According to the various aspects of the device 8, the detection circuit 4 can be in the form of a theft deterrent mechanism 22 that includes an operating circuit 24 that selectively places a mechanism 28 in signal communication with a power source 32. The detection circuit 4 is positioned in parallel with the operating circuit 24 and extends between the mechanism 28 and the power source 32. The detection circuit 4 includes an impedance path 36. A switch 40 operates to selectively divert an electrical signal 44 between the operating circuit 24, the detection circuit 4, and a deactivated state 46 where neither the operating circuit 24 nor the detection circuit 4 are engaged with the power source 32 and the mechanism 28. A current/voltage monitor 48 is coupled with the detection circuit 4 to detect the presence of a voltage component 52 and the presence of a current component 56 of the electrical signal 44 within the detection circuit 4. The switch 40 and the current/voltage monitor 48 are coupled with a controller 64. As discussed herein, the electrical signal 44 that can be directed through the detection circuit 4 can include the voltage component 52 and the current component 56 that are each monitored by the current/voltage monitor 48. The mechanism 28 is adapted to activate in the presence of a threshold level of the electrical signal 44. The voltage component 52 and the current component 56 are delivered by the operating circuit 24 or the detection circuit 4 and to one or more electrical components 58, typically at least two electrical components 58.

Referring again to FIGS. 1-7, in the event that the switch 40 connects the detection circuit 4 with the power source 32 and the mechanism 28, the impedance path 36 of the detection circuit 4 resists and diminishes the voltage component 52 and the current component 56 that are directed through the electrical components 58 of the mechanism 28 and through the current/voltage monitor 48. The current/voltage monitor 48 detects the voltage component 52 and the current component 56 as being present, but below the threshold levels indicative of a low-level electrical signal 110. Additionally, because the voltage component 52 and the current component 56 are below the threshold levels, the electrical components 58 of the mechanism 28 remain deactivated. In the event the current/voltage monitor 48 fails to detect either or both of the voltage component 52 and the current component 56, the current/voltage monitor 48 delivers a disconnect signal 60 to the controller 64 to activate a check signal 66. This check signal 66 can be in the form of a decoupling signal that is delivered to the operator of the vehicle 20 via an audio/visual indication that is activated in the passenger cabin or delivered to the operator via a wireless signal to a personal computing device of the operator, such as a cell phone, personal computer, wearable computing device, or other similar personal computing device. This check signal 66 can be indicative of the trailer 16 being decoupled from the vehicle 20, whether intentionally or unintentionally.

Referring again to FIGS. 1-7, the switch 40 can be in the form of a transistor that operates to selectively and alternatively connect the operating circuit 24 and the detection circuit 4 with the power source 32 and the mechanism 28. The transistor can also operate to a low-level condition for delivery of the low-level electrical signal 110 where the vehicle 20 and the trailer 16 are both deactivated.

Referring again to FIGS. 1-7, the impedance path 36 of the detection circuit 4 can be in the form of at least one resistor 90 that regulates and decreases the voltage component 52 and the current component 56 of the electrical signal 44 that can be used for activating the electrical components 58 of the mechanism 28 of the trailer 16. In this manner, the power source 32 can be attached to the operating circuit 24 for activating and operating the electrical components 58 of the mechanism 28 of the trailer 16. Where it is desired to only detect the presence of the trailer 16 being coupled with the vehicle 20, the detection circuit 4 is activated by the switch 40 to deliver the low-level electrical signal 110 to the mechanism 28 that is sufficient to confirm the presence of a closed circuit, which is indicative of the trailer 16 being attached to the vehicle 20. This low-level electrical signal 110 is insufficient, or below the threshold level, to operate the electrical components 58 of the mechanism 28, such that the electrical components 58 of the mechanism 28 remain deactivated during use of the detection circuit 4.

According to various aspects of the device 8, the impedance path 36 can also be in the form of a voltage divider that operates in a similar manner to regulate and decrease the voltage component 52 and current component 56 of the electrical signal 44 from the power source 32 to the mechanism 28 of the trailer 16 to be the low-level electrical signal 110.

Within conventional detection mechanisms, a high-resistance resistor is utilized for eliminating the current component of the operating signal such that a low-level voltage is delivered through the operating circuit to the mechanism. In these conventional devices, the voltage monitor only monitors the presence of a voltage, or a path to ground, within the circuit. It has been found that this path to ground can be replicated through the presence of moisture or corrosion within one or more contacts within the circuit such that a false positive can be received indicating the presence of a connection between the vehicle and the trailer, when no such connection exists. These false positives can be utilized for accomplishing a detachment of the trailer and the vehicle when not desired, such as during a theft of a trailer.

According to the various aspects of the device 8, as exemplified in FIGS. 1-7, the use of the detection circuit 4 described herein provides for detection of both the voltage component 52 and the current component 56 that must be verified by the current/voltage monitor 48 to verify the presence of a connection between the trailer 16 and the vehicle 20. By using the low-level electrical signal 110, the current/voltage monitor 48 can be used to detect the presence of a connection between the vehicle 20 and the trailer 16. The low-level electrical signal 110 includes a very low voltage and amperage that this low-level electrical signal 110 will not significantly draw down the electrical output of the power source 32. As described herein, use of each of the voltage component 52 and the current component 56 within the detection circuit 4 provides an accurate indication of the presence of the connection between the vehicle 20 and the trailer 16 that minimizes false alarms and also minimizes tampering that may allow for an unwanted decoupling of the trailer 16.

It is contemplated that the detection circuit 4 is activated intermittently to verify the presence of the connection between the trailer 16 and the vehicle 20. This intermittent activation can be approximately once per second or approximately once every fraction of a second or once every multiple seconds to repeatedly and continuously verify the presence of a connection between the trailer 16 and the vehicle 20. The intermittent activation of the detection circuit 4 can also be randomized to occur at various and changing intervals. The intermittent activation of the detection circuit 4 is done to ensure the presence of a connection between the trailer 16 and the vehicle 20 and also to provide insufficient time between activations of the detection circuit 4 to accomplish an intentional or unintentional detachment of the trailer 16 and the vehicle 20 without the check signal 66 or other alert being delivered to the controller 64 and the operator, as described herein. It is contemplated that more frequent activations or less frequent activations of the detection circuit 4 can be implemented depending upon the desired frequency or sensitivity of the system.

Referring again to FIGS. 1-7, it is contemplated that the detection circuit 4 is utilized when the vehicle 20 is activated, when the vehicle 20 is in a standby mode ready to be operated, or when a generator is supplying power to at least one of the vehicle 20 and the trailer 16. In this situation, small amounts of the voltage component 52 and the current component 56 can be drawn through the power source 32 for operating the detection circuit 4 without overly depleting the power source 32. It is contemplated that the power source 32 can be in the form of a battery, a power regulator, an alternator, or other similar power source, that is used for operating the vehicle 20 and/or the trailer 16. In certain aspects of the device 8, the detection circuit 4 may not be implemented in conditions where the battery of the vehicle 20 is the sole power source for the vehicle 20 and the trailer 16, indicative of a deactivated state 46.

The mechanism 28 of the trailer 16 includes a plurality of operating states. These operating states can include, but are not limited to, a low-power state, where the vehicle 20 is deactivated and operating on battery power only, a detection state where the switch 40 is coupled with the detection circuit 4 and power in the form of the low-level electrical signal 110 is provided to the vehicle 20 and/or the trailer 16 by more than just the battery of the vehicle 20, and an operating state where the switch 40 is coupled with the operating circuit 24 and the vehicle 20 is fully powered for providing electrical current to both the vehicle 20 and the trailer 16. The electrical components 58 of the mechanism 28, according to the various aspects of the device 8, can be in the form of one or more light sources, a theft detection device, a braking system, combinations thereof, or other similar mechanism that can be activated using the operating circuit 24 and can receive the low-level electrical signal 110 from the detection circuit 4.

As described herein, the electrical components 58 of the mechanism 28 are able to be operated using the operating circuit 24 with the electrical signal 44 being provided therethrough. When the detection circuit 4 is utilized, the switch 40 couples the detection circuit 4 with the power source 32 and the electrical components 58 of the mechanism 28 and delivers the low-level electrical signal 110 through the detection circuit 4 and the impedance path 36. The impedance path 36 of the detection circuit 4 decreases the voltage component 52 and the current component 56 of the electrical signal 44 to be below the threshold level of the electrical signal 44 that is insufficient to operate the electrical components 58 of the trailer 16. Using the detection circuit 4, the electrical components 58 remain deactivated and the current/voltage monitor 48 is able to detect the presence of a closed circuit and monitor the voltage component 52 and the current component 56 of the low-level electrical signal 110 that is below the threshold level of the electrical signal 44 to be able to activate the mechanism 28.

According to the various aspects of the device 8, the impedance path 36 of the detection circuit 4 can include a resistor 90. This resistor 90 can have a resistance of approximately 100 kiloohms. It is contemplated that resistors 90 having greater or lower resistance can be utilized within the detection circuit 4, so long as the resulting voltage component 52 can be detected by the current/voltage monitor 48 and the electrical components 58 of the mechanism 28 remain deactivated. The detection circuit 4 is utilized to reduce the voltage component 52 and the current component 56 of the electrical signal 44 to be below the operating parameters of the particular electrical components 58 of the mechanism 28, such as the trailer 16. As described herein, when the detection circuit 4 is activated, the electrical components 58 of the mechanism 28 remain deactivated while the operating circuit 24 is closed, such that the current/voltage monitor 48 can detect the presence of the voltage component 52 and the current component 56 of the low-level electrical signal 110.

Utilizing the one or more resistors 90 that form the impedance path 36 of the detection circuit 4, the current component 56 is decreased. Such decrease can, by way of example, and not limitation, be within a typical range of from approximately 5 microamps to approximately 200 microamps and typically within a range of approximately 50 microamps to approximately 80 microamps. Other ranges of the current component 56 can be utilized to maintain the mechanism 28 as being activated, while also allowing the current/voltage monitor 48 to detect the presence of the voltage component 52 and the current component 56 of the low-level electrical signal 110. Only where the voltage component 52 and the current component 56 are both detected is the presence of the connection between the vehicle 20 and the trailer 16 verified. The check signal 66 is delivered to the operator where one or both of the voltage component 52 and the current component 56 are not detected by the current/voltage monitor 48. Additionally, the check signal 66 can be delivered where each of the electrical components 58 do not receive the low-level electrical signal 110. As described herein, the use of multiple electrical components 58 can prevent false alarms where one of the electrical components 58 is deactivated, such as because of a short circuit, or other malfunction. The lack of the low-level electrical signal 110 to all of the electrical components 58 is indicative of a disconnecting event between the vehicle 20 and the trailer 16.

According to the various aspects of the device 8, the detection circuit 4 described herein can be utilized for different strategies for accomplishing different use cases. By way of example, and not limitation, the detection circuit 4 can be utilized for detecting the occurrence of an unintentional detachment between the vehicle 20 and the trailer 16, such as during transport or other motion of the vehicle 20 and trailer 16. Additionally, certain theft techniques seek to replicate one of the voltage component 52 (or path to ground) or the current component 56 of the particular electrical signal 44. Using the detection circuit 4 described herein, each of the voltage component 52 and the current component 56 must be present, in combination with the activation of the switch 40, to verify the presence of the trailer 16. Where any one of these electrical components 58 are not present or are out of congruence with one another, such as the voltage component 52, the current component 56, or the contemporaneous activation of the switch 40, the disconnect signal 60 is delivered to the controller 64 and the check signal 66 is delivered to the operator. In certain aspects of the device 8, the check signal 66 can be delivered directly without first delivering a separate disconnect signal 60. As described herein, the check signal 66 is used to notify the operator that a decoupling event may be occurring and the presence of the trailer 16 and a connection thereof should be verified.

According to the various aspects of the device 8, the detection circuit 4 can be utilized in applications other than the vehicle and trailer application. In various situations where the presence of a connection between two components needs to be verified without activating one of the mechanisms 28, the detection circuit 4 described herein can be utilized for delivering the low-level electrical signal 110 that can be detected, but is below a threshold needed to activate the connected mechanisms 28. Again, using the detection circuit 4, the mechanism 28 remains deactivated while the current/voltage monitor 48 verifies the presence of a voltage component 52 and a current component 56 of a particular electrical signal 44.

Utilizing the detection circuit 4 described herein, very low levels of the electrical power are provided to the detection circuit 4 for monitoring the presence of a connection between the power source 32 and particular electrical components 58 of the mechanism 28. The detection circuit 4 described herein provides multiple markers, in the form of the voltage component 52 and the current component 56, for verifying the presence of a connection between the power source 32 and a particular mechanism 28.

The current/voltage monitor 48 can also be calibrated to detect a particular value or range of values of the voltage component 52 and the current component 56 that is delivered through the detection circuit 4. Where either one of these parameters is out of sync with an expected value, the controller 64 can be notified that a decoupling event may be occurring, or has occurred. Accordingly, the power source 32 and the impedance path 36 of the detection circuit 4 can be calibrated to provide a certain electrical signal 44 from the power source 32 and to allow a certain low-level electrical signal 110 to pass through the impedance path 36 of the detection circuit 4. In this manner, the current/voltage monitor 48 can be programmed to expect a certain low-level electrical signal 110 that is within a certain range of values. In this manner, the detection circuit 4 can generate an expected voltage component 52 and an expected current component 56 through the impedance path 36. Where the expected voltage component 52 and the expected current component 56 of the impedance path 36 are not detected by the current/voltage monitor 48, the controller 64 can be notified that a decoupling event has occurred.

According to the various aspects of the device 8, as exemplified in FIGS. 1-7, the detection circuit 4 can be installed within a theft deterrent mechanism 22. This theft deterrent mechanism 22 can be installed within the trailer 16. In particular, the trailer 16 can include an integrated trailer control module (ITCM) 120, where the detection circuit 4 is installed or incorporated within the ITCM 120. The ITCM 120 is designed to monitor the various connections, such as electrical connections, between the vehicle 20 and the trailer 16. The ITCM 120 also monitors unauthorized or unwanted disconnection events. The vehicle 20, such as a tractor, is attached to the trailer 16 via a harness 122. This harness 122 provides for the connection between electrical components 58 of the trailer 16 and a board 144 for the ITCM 120 that is typically located within the vehicle 20. The ITCM 120 monitors unauthorized disconnections within the harness 122, such as during a theft event, or during an inadvertent disconnection between the trailer 16 and the harness 122. The ITCM 120 also operates to prevent false alerts that may be caused by electrical anomalies. Through this configuration, the ITCM 120 provides a reliable embedded solution within the control module for the vehicle 20.

Referring again to FIGS. 1-7, the detection circuit 4 integrated within the ITCM 120 continuously monitors the connection at the harness 122 between the trailer 16 and the vehicle 20. This detection circuit 4 processes input signals using a discrete circuit that utilizes Boolean logic conditions to confirm a real disconnection. The detection circuit 4 also distinguishes between normal operation, a fault condition, and an actual harness removal. When an actual harness disconnection is detected, the detection circuit 4 triggers the check signal 66, such as a theft indication signal, and sends an alert to the operator via a controller 64 for the vehicle 20. This check signal 66 is delivered to the vehicle 20 such that a user or operator of the vehicle 20 can observe, visually or auditorily, the check signal 66 and address a particular situation.

According to the various aspects of the device 8, the electrical components 58 of the trailer 16 are attached to the detection circuit 4. As described herein, the current/voltage monitor 48 detects the delivery of an electrical signal 44 to multiple, and typically two, electrical components 58 of the trailer 16. These electrical components 58 can be in the form of a right turn lamp 140 and a left turn lamp 142 of the trailer 16. Typically, where each of the right turn lamp 140 and the left turn lamp 142 have no electrical signal 44 delivered thereto, the current/voltage monitor 48 fails to detect the electrical signal 44 and activates the delivery of the check signal 66 to the vehicle 20. The board 144 for the ITCM 120 includes respective drivers 146 for the right turn lamp 140 and the left turn lamp 142. These drivers 146 operate to deliver the respective electrical signals 44 to each of the right turn lamp 140 and the left turn lamp 142. Where the harness 122 is disconnected, this electrical signal 44 cannot be provided. The absence of the low-level electrical signal 110 as detected by the current/voltage monitor 48 is communicated to the controller 64 and the check signal 66 is delivered by the system basis chip (SBC) 148. Under typical operating conditions, the drivers 146 for the right turn lamp 140 and the left turn lamp 142 within the ITCM 120 are connected with the operating circuit 24 and the detection circuit 4. Operation of the switch 40, as described herein, determines whether the driver 146 delivers the electrical signal 44 or the low-level electrical signal 110 to each of the right turn lamp 140 and the left turn lamp 142 of the trailer 16.

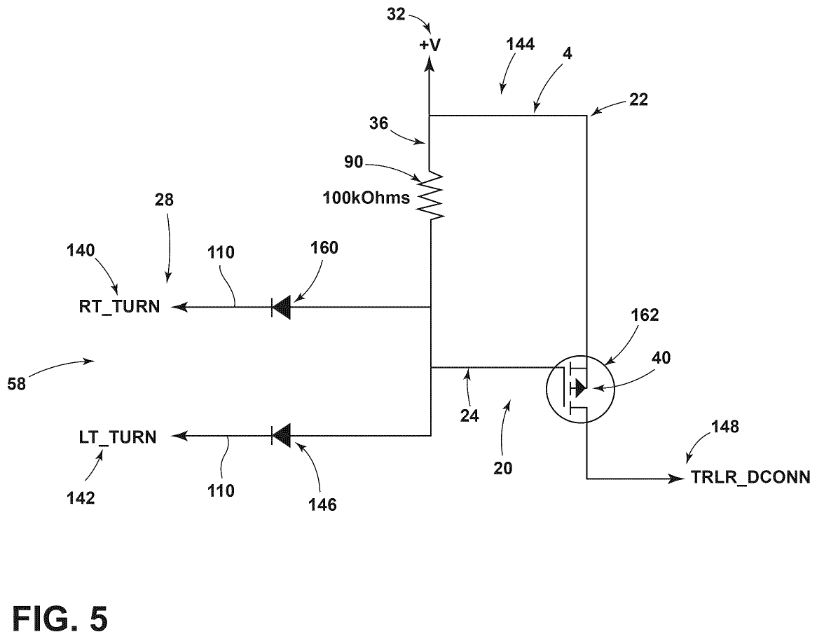

As exemplified in FIGS. 5-7, the detection circuit 4 described herein can utilize various diodes 160 and transistors 162, such as MOSFET transistors, for controlling the flow of the electrical signal 44 therethrough. The detection circuit 4 can receive power through a battery (VBT) or a power regulator (VPRE). The SBC 148 is triggered when the electrical components 58 of the trailer 16 are disconnected such that the current/voltage monitor 48 does not detect the presence of the voltage component 52 or the current component 56 of the low-level electrical signal 110. As described herein, the electrical components 58 typically include two separate components, such as a right turn lamp 140 and a left turn lamp 142 of the trailer 16. The detection circuit 4 requires a 2-input NOR (both false) gate logic to activate delivery of the check signal 66 from the SBC 148. Accordingly, where both the right turn lamp 140 and the left turn lamp 142 are disconnected from the harness 122, the check signal 66 indicative of a disconnection of the trailer 16 is provided. This 2-input NOR gate logic is used to prevent false alerts where there is a disconnection or electrical malfunction in only one of the electrical components 58.

Where the electrical components 58 are disconnected, the detection circuit 4 provides a wake signal, such as the disconnect signal 60, to the SBC 148. In turn, the SBC 148 can be used to deliver the check signal 66 to the operator, the passenger cabin of the vehicle 20, or other similar location to alert the operator of a disconnection event with respect to the trailer 16, as described herein. Where the electrical components 58 remain connected, the electrical signal 44 delivered to the current/voltage monitor 48 and the electrical components 58 remains the low-level electrical signal 110 that is below the threshold. As described herein, where the electrical signal 44 is below the threshold, the low-level electrical signal 110 is insufficient to activate the electrical components 58. Contemporaneously, this low-level electrical signal 110 can be detected by the current/voltage monitor 48. So long as the low-level current component 56 is detected by the current/voltage monitor 48, no wake signal or disconnect signal 60 is provided to the SBC 148 and no check signal 66 is provided by the SBC 148 to the controller 64 for the vehicle 20. When the electrical components 58 are disconnected, such as a disconnection at the harness 122, no electrical signal 44 is provided through the current/voltage monitor 48, or to the electrical components 58. In this condition, the SBC 148 provides the check signal 66 to the vehicle 20 to alert the operator that there has been a disconnection event between the trailer 16 and the vehicle 20.

According to the various aspects of the device 8, in conditions where one of the two electrical components 58 are disconnected, such as through a short circuit, burned out bulb, or other electrical malfunction, the presence of the electrical circuit in the other of the electrical components 58 prevents the delivery of the disconnect signal 60 to the SBC 148 and also prevents delivery of the check signal 66 from the SBC 148 to the controller 64. As described herein, all electrical components 58 that are connected with the detection circuit 4 and the current/voltage monitor 48 must be in a deactivated state 46 in order for the check signal 66 to be provided by the SBC 148.

According to the various aspects of the device 8, certain mechanisms 28 include a field effect transistor 162 that includes a conventional detection mechanism for detecting the presence of a path to ground between a power source 32 and a particular mechanism 28. As described herein, these conventional detection mechanisms detect only path to ground and can be replicated through moisture within a particular contact or corrosion within one of the contacts. The detection circuit 4 described herein is provided as a parallel or supplemental detection circuit that operates in conjunction with the circuitry of the field effect transistor 162. Additionally, the field effect transistor 162 and the detection circuit 4 described herein are typically configured to operate under different conditions and use cases. The resistor 90 incorporated within the field effect transistor 162 has typically high resistive features such as a resistor 90 of approximately 1 megaohms that provides a weak path to ground within the circuitry of the field effect transistor 162 and the mechanism 28. This weak path to ground, as described herein, can be replicated due to presence of moisture or corrosion contacts. This pattern can also be replicated during attempted theft of the device 8 to which the mechanism 28 is attached, such as a trailer 16, or other similar mechanism. The detection circuit 4 described herein is utilized when a power source 32 other than the battery of the vehicle 20 is used for providing electrical power to the vehicle 20 and the trailer 16.

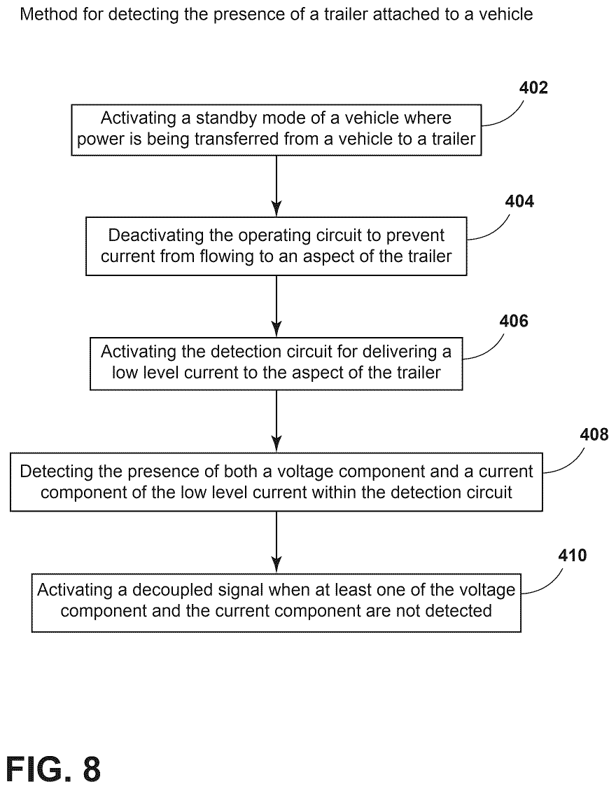

Referring again to FIGS. 1-8, having described various aspects of the device 8, a method 400 is disclosed for detecting the presence of a connection between a trailer 16 and a vehicle 20. According to the method 400, step 402 includes activating a standby mode 180 of the vehicle 20, where power, in the form of the electrical signal 44, is being transferred from a vehicle 20 to a trailer 16. This electrical signal 44 is delivered to the trailer 16 by more than just a battery of the vehicle 20. This electrical signal 44 is delivered typically through an alternator, generator, or other supplemental power source. The battery of the vehicle 20 may be used as a supplemental source of the electrical signal 44. According to the method 400, the operating circuit 24 is deactivated to prevent the electrical components 58 of the mechanism 28 within the trailer 16 from being activated (step 404). The detection circuit 4 is then activated for delivering a low-level electrical signal 110 to the electrical components 58 of the trailer 16 (step 406). As described herein, this detection circuit 4 includes the impedance path 36 that delivers the voltage component 52 and the current component 56 of the low-level electrical signal 110 from the power source 32. When the detection circuit 4 is activated, the presence of both the voltage component 52 and the current component 56 of the low-level electrical signal 110 are detected within the detection circuit 4, typically using the current/voltage monitor 48 (step 408). A decoupling signal is activated when at least one of the voltage component 52 and the current component 56 are not detected (step 410).

Utilizing the detection circuit 4 described herein, multiple use cases of theft prevention and inadvertent detachment of a particular connection can be provided for. These use cases can include theft, inadvertent decoupling, damage, combinations thereof, and other similar use cases to determine the presence of electrical connection between a power source 32 of one mechanism, such as the vehicle 20, and aspects of another mechanism, such as a trailer 16.

It will be understood by one having ordinary skill in the art that construction of the described disclosure and other components is not limited to any specific material. Other exemplary embodiments of the disclosure disclosed herein may be formed from a wide variety of materials, unless described otherwise herein.

What is claimed is:

1. A disconnect detection device comprising:
an operating circuit that places a mechanism in signal communication with a power source;
a detection circuit that is positioned in parallel with the operating circuit and extending between the mechanism and the power source, the detection circuit defining an impedance path;
a switch that selectively diverts an electrical signal between the operating circuit and the detection circuit; and
a current/voltage monitor that is coupled with the detection circuit to detect the presence of a voltage component of the electrical signal and the presence of a current component of the electrical signal within the detection circuit, wherein the switch and the current/voltage monitor are coupled with a controller; wherein
the mechanism is adapted to activate in the presence of a threshold level of the current component and the voltage component that are delivered by the operating circuit;
in the event that the switch connects the detection circuit with the power source and the mechanism, the impedance path directs at least the current component through the mechanism and through the current/voltage monitor as a low-level electrical signal of the current component that is below the threshold level such that the mechanism remains deactivated; and
in the event that the current/voltage monitor fails to detect the current component, the current/voltage monitor delivers a check signal to the controller.

2. The disconnect detection device of claim 1, wherein the low-level electrical signal of the current component is capable of detection by the current/voltage monitor, and wherein the mechanism remains deactivated when the mechanism receives the low-level electrical signal of the current component.

3. The disconnect detection device of claim 1, wherein the impedance path is defined by one of a resistor and a voltage divider.

4. The disconnect detection device of claim 1, wherein the switch is a transistor.

5. The disconnect detection device of claim 1, wherein the mechanism includes a right turn lamp and a left turn lamp of a trailer.

6. The disconnect detection device of claim 5, wherein the current/voltage monitor delivers the check signal to the controller in the event that the current component for delivery to the right turn lamp and the left turn lamp is undetected by the current/voltage monitor.

7. The disconnect detection device of claim 1, wherein the check signal is delivered to a trailer for alerting an operator of the trailer.

8. The disconnect detection device of claim 1, wherein the check signal activates a theft deterrent mechanism of a trailer.

9. The disconnect detection device of claim 1, wherein the low-level electrical signal of the current component is approximately 50 microamps.

10. The disconnect detection device of claim 1, wherein the impedance path of the detection circuit also defines the voltage component of the electrical signal as being the low-level electrical signal that is below the threshold level.

11. The disconnect detection device of claim 1, wherein the power source includes at least one of a battery and a power regulator.

12. A disconnect detection device comprising:
an operating circuit that places a trailer in signal communication with a power source of a vehicle;
a detection circuit that is positioned in parallel with the operating circuit and extending between the trailer and the power source, the detection circuit defining an impedance path;
a switch that selectively diverts an electrical signal between the operating circuit and the detection circuit, the electrical signal having a voltage component and a current component; and
a current/voltage monitor that is coupled with the detection circuit to detect the presence of at least the current component within the detection circuit, wherein the switch and the current/voltage monitor are coupled with a controller; wherein
the trailer includes electrical components that define an operating state in the presence of the voltage component and the current component that are delivered by the operating circuit and define a threshold level of the voltage component and the current component;
in the event that the switch connects the detection circuit with the power source and the trailer, the impedance path defines at least the current component as being at a low-power state where the voltage component and the current component are below the threshold level such that the electrical components of the trailer remain deactivated; and
in the event that the current/voltage monitor fails to detect the current component, the current/voltage monitor delivers a check signal to the controller.

13. The disconnect detection device of claim 12, wherein the impedance path is defined by one of a resistor and a voltage divider.

14. The disconnect detection device of claim 12, wherein the switch is a transistor.

15. The disconnect detection device of claim 12, wherein the electrical components are at least one of a light source, a theft detection device, and a braking system of the trailer.

16. The disconnect detection device of claim 12, wherein the controller, in response to receiving the check signal, is configured to deliver a decoupling signal to the trailer for alerting an operator of the trailer.

17. The disconnect detection device of claim 16, wherein the decoupling signal activates a theft deterrent mechanism of the trailer.

18. The disconnect detection device of claim 16, wherein the low-power state of the current component is approximately 50 microamps.

19. A method for detecting the presence of a trailer attached to a vehicle, the method comprising steps of:
activating a standby mode of the vehicle where power is being transferred from the vehicle to the trailer;
deactivating an operating circuit to prevent current from flowing to an aspect of the trailer;
activating a detection circuit for delivering a low-level electrical signal to the aspect of the trailer, wherein the low-level electrical signal includes a voltage component and a current component that are below a threshold level, the low-level electrical signal being a minimum electrical signal that is capable of being detected and incapable of activating the aspect of the trailer;
detecting the presence of both the voltage component and the current component of the low-level electrical signal within the detection circuit; and
activating a decoupling signal when at least the current component is not detected.

20. The method of claim 19, wherein the decoupling signal activates a theft deterrent mechanism of at least one of the vehicle and the trailer.
